(19) United States
(12) Patent Application Publication
(10) Pub. No.: US 2008/0283088 A1
(43) Pub. Date: Nov. 20, 2008

(54) PLASMA PROCESSING APPARATUS, PLASMA PROCESSING METHOD AND CLEANING TIME PREDICTION PROGRAM

(76) Inventors: Miki Shima, Toyama (JP); Shinichi Imai, Osaka (JP)

Correspondence Address: MCDERMOTT WILL & EMERY LLP, 600 13TH STREET, NW, WASHINGTON, DC, 20005-3096, US

(21) Appl. No.: 12/121,433

(22) Filed: May 15, 2008

(30) Foreign Application Priority Data
May 16, 2007 (JP) 2007-130983

(51) Int. Cl. H01L 21/306; C23C 16/00; B08B 6/00

(52) U.S. Cl. 134/1.1; 118/723 R; 156/345.24

(57) ABSTRACT

The plasma processing apparatus relating to the present invention has a measurement circuit for measuring an antenna bias voltage that varies according to an amount of electrical charge between an inner wall of a chamber and plasma generated in the chamber. The obtained antenna bias voltage is converted to a statistical value and is stored in a statistical value memory unit after being associated with a number of particles attached on a workpiece during the same plasma processing that the antenna bias voltage is obtained. A correspondence acquisition unit obtains a correspondence the antenna bias voltage and the number of particles based on stored data in the statistical value memory. Then, a prediction unit predicts the antenna bias voltage at which the number of particles reaches to a pre-determined value based on the correspondence obtained by the correspondence acquisition unit.

### CROSS-REFERENCE TO RELATED APPLICATION

The present application claims the benefit of Japanese Patent Application No. 2007-130983 filed May 16, 2007, the subject matter of which is incorporated herein by reference.

### BACKGROUND OF THE INVENTION

1. Field of the Invention

The present invention relates to plasma processing apparatus and method for processing a workpiece with plasma, and its cleaning time prediction program.

2. Description of the Related Art

In recent years, plasma processing has become an essential technique for applications such as microfabrication or thin-film formation, especially for manufacturing very large Scale integrated circuit devices in the field of semiconductors. Plasma processing apparatuses to perform such plasma processing include dry etching apparatuses, plasma CVD (Chemical Vapor Deposition) apparatuses and sputtering apparatuses. In addition, methods to excite plasma adopted in each plasma processing apparatus vary as in parallel plate type, inductively-coupled type, ECR (Electron Cyclotron Resonance) type, microwave excited type and the like. Since high density plasma has been generated under high vacuum during the plasma processing process in recent years, inductively-coupled typed plasma processing apparatuses are widely used.

FIG. 5 is a schematic diagram showing a parallel plate type plasma processing apparatus as an example of conventional plasma processing apparatuses. As shown in FIG. 5, the plasma processing apparatus comprises a vacuum processing chamber 101, capable of reducing pressure. A workpiece 104 is placed on a lower electrode 103 in the vacuum processing chamber 101. On the opposite side of the lower electrode 103, an upper electrode 106 is placed. When the present plasma processing apparatus is a dry etching apparatus, etching gas (process gas) is delivered to the vacuum processing chamber 101 from a gas delivering unit 105. At this time, pressure in the vacuum processing chamber 101 is maintained at a specified level by a vacuum evacuation unit 102. In this state, for example, when a high-frequency power supply 107 applies high-frequency power to the lower electrode 103 via a matching box 108, plasma is generated by an electric field generated between the lower electrode 103 and the upper electrode 106. The workpiece 104 exposed to the plasma is etched by the action of plasma.

On the other hand, when etching processing or film formation processing is performed in the plasma processing apparatus, the reaction product adheres to the inner wall of the vacuum processing chamber 101. The thickness of such reaction product increases as the plasma processing is repeated. As the adhered reaction product increases, plasma processing conditions such as etching property or film formation property change. It is not easy to directly monitor such changes over time of the inner wall of the vacuum processing chamber 101 from the outside of the apparatus.

Therefore, the conditions of plasma processing are indirectly monitored by continuously obtaining control parameters such as high-frequency power, inner pressure of the vacuum processing chamber, flow rate of process gas and matching status of the matching box during plasma processing. Normal ranges of each control parameter are pre-set, and when monitored values of the control parameters deviate out of the predetermined range, an “anomaly” is determined to exist. The plasma processing apparatus adopts an inter-lock method to stop the motion of the plasma processing apparatus to minimize the generation of the products with poor quality.

For example, Japanese Laid-Open Patent Publication No. 2003-23001 discloses a method to detect anomalies of an etching rate based on fundamental waves and higher harmonics waves of current, voltage and phase difference of plasma excitation electrode (lower electrode 103 in FIG. 5). With this method, a correlation expression between fundamental waves and higher harmonics waves of current, voltage, and phase difference, and an etching rate is pre-created. When the etching rate calculated from the fundamental waves and higher harmonic waves of the current, voltage, and phase difference which are detected at etching deviate from the predetermined range, an anomaly is determined to exist. The etching rate anomaly can be detected by this method with a high degree of accuracy.

Furthermore, Japanese Laid-Open Patent Publication No. 2005-117071 discloses a method for detecting anomalies inside of a vacuum processing chamber by measuring at least one physical value of impedance of a system including plasma, voltage between peaks of a high frequency signal applied to plasma, and self-bias voltage applied to a plasma excitation electrode. In this method, a measured physical value is compared to a pre-determined value, and if the measured value is not equal to the pre-determined value, the process is shut down. At the same time, a signal is sent indicating that it is time to clean the vacuum processing chamber. According to this method, it is capable of externally detecting the inner wall conditions of the vacuum processing chamber. Furthermore, changes are suppressed over time by determining the cleaning time appropriately or controlling etched shapes.

### SUMMARY OF THE INVENTION

Now, the reaction product adhered to the inner wall of the vacuum processing chamber 101 is detached as the film becomes thicker, generating particles. When the particles attach to the workpiece 104, defects result. Therefore, in the plasma processing apparatus, cleaning is periodically performed to eliminate the reaction product adhered to the inner wall of the vacuum processing chamber 101. Based on past experience, the timing of the cleaning is determined according to accumulated process time or accumulated process count. However, since each plasma processing (amount of film formation or etching) is not identical when various kinds of products are manufactured in small quantity, it is possible that the amount of reaction product adhered to the inner wall of the vacuum processing chamber 101 is not the same even though the accumulated process time or the accumulated process count are the same. Furthermore, due to the time deterioration of the apparatus over time, it is possible that the amount of adhered reaction product is not the same even though the plasma processing is performed under the same conditions. Therefore, with this method, to perform cleaning on a regular basis, it is likely that each cleaning will not be performed at an appropriate cleaning time. If the cleaning time is too late, particle-derived defects occur or if the cleaning time is too early, the operating rate of the plasma processing apparatus decreases. In any event, there is the problem of increased manufacturing costs.

With the above-mentioned prior art, the anomaly of the plasma processing condition can be detected. However, it is not necessary that such detected anomaly is derived from the reaction product adhered to the inner wall of the vacuum processing chamber 101. Furthermore, during the plasma processing step of semiconductor devices and the like, the upper limit of the particle count attached on the workpiece caused by plasma processing is determined from the standpoint of quality assurance. However, these prior art does not take into account the particle count. Therefore, the cleaning time cannot be determined based on the particle count.

In addition, it cannot be determined with the above prior art as to how many times the plasma processing can be performed from now to the next cleaning time. Furthermore, there the problem that the operating rate of the apparatus decreases, since the operation of plasma processing apparatus cannot be regulated in conjunction with a production management system even if the anomaly is detected.

The present invention is proposed in view of the above-described circumstances and the purpose of the present invention is to provide a plasma processing apparatus and a method capable of determining the appropriate cleaning time based on the particle count, and its cleaning time prediction program.

In order to resolve the above-described problems, the present invention utilizes the following technical means. Firstly, the present invention is on the premise a plasma processing apparatus for performing plasma processing of a workpiece in a vacuum processing chamber using plasma generated in the vacuum processing chamber by applying high-frequency power to a plasma excitation electrode. Then, in the plasma processing apparatus according to the present invention, a measurement circuit obtains a physical value which varies according to an amount of electrical charge between an inner wall of the vacuum processing chamber and the plasma generated in the vacuum processing chamber. A statistical value memory unit records by associating the physical value obtained by the measurement circuit with a number of particles attached on the workpiece during the plasma processing in which the physical value is obtained. A correspondence acquisition unit obtains a correspondence between the physical value and the number of particles based on the physical values and the numbers of particles obtained from a multiple rounds of the plasma processing stored in the statistical value memory unit. Then, a prediction unit predicts the physical value at which the number of particles reaches to a predetermined specified value based on the correspondence obtained by the correspondence acquisition unit For example, the physical value is a self-bias potential of the plasma excitation electrode.

Furthermore, the above plasma processing apparatus may further comprise a determination unit for determining whether a cleaning of the vacuum processing chamber is needed or not by comparing the physical value predicted by the prediction unit and the physical value obtained during the plasma processing thereafter. In addition, the above plasma processing apparatus may further comprise a cleaning time calculator for obtaining a correspondence between the physical values obtained from a multiple rounds of the plasma processing and an accumulated process time or an accumulated process count after the cleaning of the vacuum processing chamber. The cleaning time calculator predicts the remaining process time reaching to the predicted physical value based on the correspondence between the physical value and the accumulated process time or a remaining process count reaching to the predicted physical value based on the correspondence between the physical value and the accumulated process count.

Furthermore, the above plasma processing apparatus may further comprise a cleaning management unit for determining a cleaning time of the vacuum processing chamber based on the remaining process time or the remaining process count predicted by the cleaning time calculator and a production schedule for workpieces to be plasma-processed. It is preferable that when the above production schedule is modified, the cleaning management unit determines the cleaning time of the vacuum processing chamber according to the modified production schedule.

On the other hand, from another point of view, the present invention can provide a plasma processing method for performing plasma processing of a workpiece in a vacuum processing chamber using plasma generated in the vacuum processing chamber by applying high-frequency power to a plasma excitation electrode. That is, in the plasma processing method according to the present invention, first, a physical value which varies according to an amount of electrical charge between an inner wall of the vacuum processing chamber and the plasma generated in the vacuum processing chamber, is obtained. Next, the obtained physical value is associated with a number of the particles attached on the workpiece during the plasma processing in which the physical value is obtained. Furthermore, a correspondence between the physical value and the number of particles is obtained based on the physical values and the numbers of particles obtained from a multiple rounds of the plasma processing. Then, the physical value at which the number of particles reaches to a pre-determined specified value based on the correspondence is predicted. For example, a self-bias potential of the plasma excitation electrode can be adopted as the physical value.

Furthermore, it may be determined that whether a cleaning of the vacuum processing chamber is necessary or not by comparing the predicted physical value with the physical value obtained during the plasma processing thereafter.

Furthermore, the plasma processing method according to the present invention can predict a cleaning time by the following processes. First, a correspondence between the physical values obtained from a multiple rounds of the plasma processing and an accumulated process time or an accumulated process count of the vacuum processing chamber after the cleaning of the vacuum processing chamber is obtained. Then, a remaining process time reaching to the predicted physical value based on the correspondence between the physical value and the accumulated process time is predicted. Or, a remaining process count reaching to the predicted physical value based on the correspondence between the physical value and the accumulated process count is predicted. Furthermore, a cleaning time of the vacuum processing chamber is determined based on the remaining process time or remaining process count predicted in this manner and a production schedule for workpieces to be plasma-processed. It is preferable that when the above production schedule is modified, it determines the cleaning time of the vacuum processing chamber according to the modified production schedule.

The other aspect of the present invention is that the present invention can provide a computer program for performing the procedures of the above mentioned plasma processing method.

According to the present invention, it can be determined whether the inside of the vacuum processing chamber is the condition that particles are likely to fall off or not even during the plasma processing. Therefore, the plasma processing can be stopped before particles larger than the standard size falls on the workpiece. Furthermore, the cleaning time can be determined when the particle count increases. As a result, the amount of reaction product adhered to the inner wall of the vacuum processing chamber can be always maintained within a specified range to prevent substandard particles from attaching on the workpiece.

Furthermore, the operation rate of the apparatus can be improved since the production schedule can be determined based on the determined cleaning time.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram showing a plasma processing apparatus according to a first embodiment of the present invention.

FIGS. 2A and 2B are diagrams showing the relationship between the average value of the antenna bias voltage and the particle count according to the first embodiment of the present invention.

FIG. 3 is a schematic diagram showing a plasma processing apparatus according to a second embodiment of the present invention.

FIGS. 4A and 4B are diagrams showing the relationship between the average value of antenna bias voltage and the particle count according to the second embodiment of the present invention.

FIG. 5 is a schematic diagram showing a conventional plasma processing apparatus.

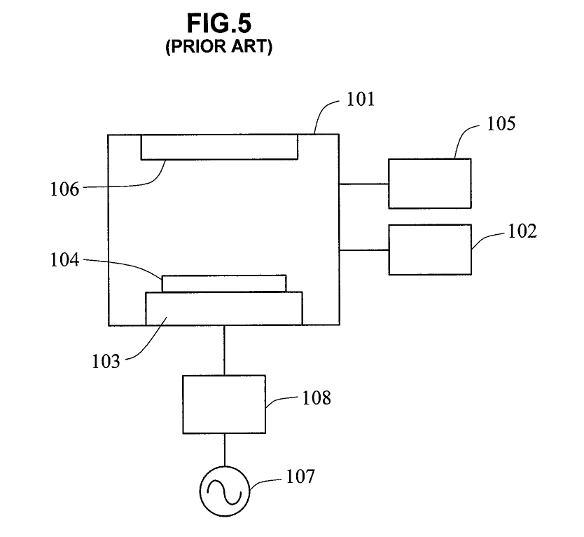

### DETAILED DESCRIPTION OF PREFERRED EMBODIMENTS

Embodiments according to the present invention are described hereafter, with reference to the drawings. The present invention is embodied as an ECR type dry etching apparatus in the following embodiments.

### FIRST EMBODIMENT

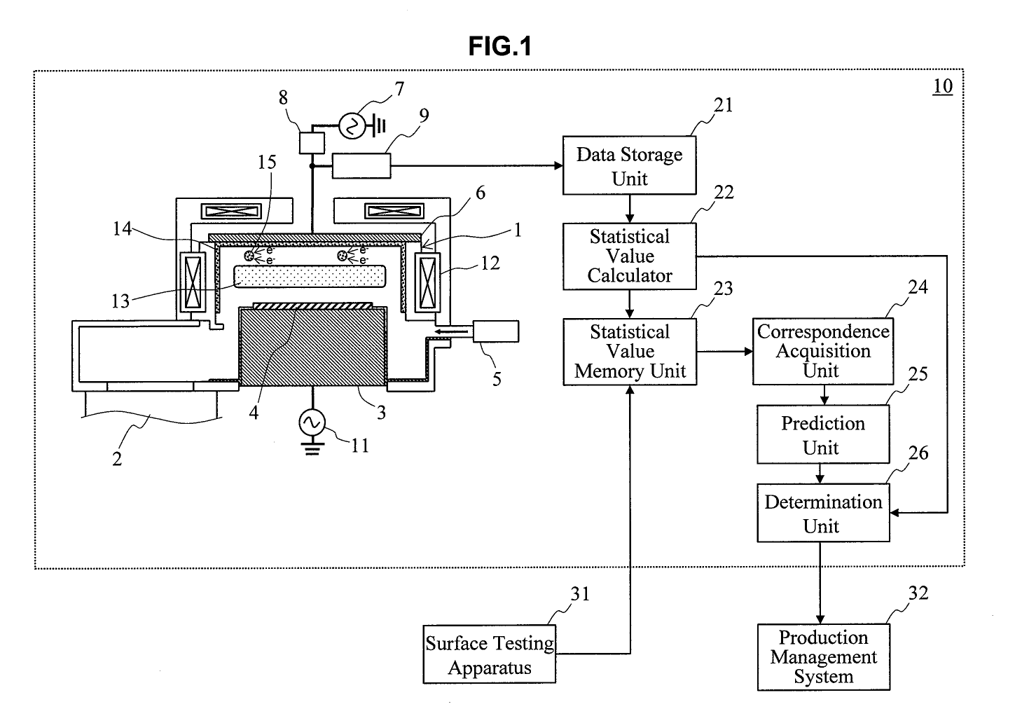

A first embodiment according to the present invention is described in detail hereafter with reference to FIG. 1. FIG. 1 is a schematic diagram showing the plasma processing apparatus 10 of the present embodiment As shown in FIG. 1, the plasma processing apparatus 10 comprises a vacuum processing chamber 1, which is designed to be capable of reducing pressure. A workpiece 4 such as semiconductor wafer (hereafter, referred to as a wafer 4) is placed on a lower electrode 3 in the vacuum processing chamber 1. The present embodiment takes a configuration in which the wafer 4 is placed on the lower electrode 3.

An upper electrode 6 is placed on the opposite side of the lower electrode 3. Etching gas is delivered as process gas to the vacuum processing chamber 1 via a gas delivering unit 5 connected on the side wall of the vacuum processing chamber 1. At this time, pressure in the vacuum processing chamber 1 is maintained at a specified level by a vacuum evacuation unit 2. In this state, for example, a high-frequency power supply 7 provides high-frequency power in an UHF range or VHF range to the upper electrode 6 (plasma excitation electrode) via a matching box 8. By the action of the high-frequency power and a coil 12 placed on the outer circumference of the vacuum processing chamber 1, plasma 13 is excited between the lower electrode 3 and the upper electrode 6. The etching process is performed by the surface of the wafer 4 being exposed to the plasma 13. In addition, in the plasma processing apparatus 10, the high-frequency power supply 11 provides high frequency power to the lower electrode 3 during plasma processing to generate substrate bias potential on the lower electrode 3 that the wafer 4 is placed on.

In addition, the plasma processing apparatus 10 comprises a measurement circuit 9 between the matching box 8 and the upper electrode 6 for measuring bias potential of the upper electrode 6 (hereafter, referred to as antenna bias voltage) during plasma processing. The measurement circuit 9 measures the antenna bias voltage by measuring a high-frequency signal applied to the upper electrode 6 during plasma processing. For example, the measurement circuit 9 obtains at least one period of the high-frequency voltage applied to the upper electrode 6 and obtains the antenna bias voltage by obtaining direct current component of the high-frequency voltage. The measurement circuit 9 performs the antenna bias voltage acquisition in real-time at a fixed sampling period (for example, 1 Hz). The antenna bias voltage indicates the electrical potential of the upper electrode 6 with respect to the inner wall of the vacuum processing chamber 1 during plasma processing.

Furthermore, the plasma processing apparatus 10 of the present embodiment comprises a data storage unit 21, a statistical value calculator 22, a statistical value memory unit 23, a correspondence acquisition unit 24, a prediction unit 25 and a determination unit 26. Each function of the units 21-26 will be described hereafter.

In the plasma processing apparatus 10 with the above configuration, reaction product 14 is generated from the reaction between active species such as radicals and ions in the plasma 13 and an object to be etched on the surface of the wafer 4 during the etching process. The reaction product 14 is adhered to the inner wall of the vacuum processing chamber 1 or to parts placed in the vacuum processing chamber 1 during etching process. The film thickness of the reaction product 14 becomes thicker as plasma processing the wafer 4 is performed. Then, particles 15 are generated in the vacuum processing chamber 1 when the adhered reaction product 14 in the vacuum processing chamber 1 falls off of its own weight, shock by the plasma 13 or temperature change of the vacuum processing chamber 1. In a case that the particles 15 fall on the wafer 4, the yield of the plasma processing decreases.

The inventors of the present invention have obtained the following knowledge while paying attention to the variations of the antenna bias voltage during the generation process of the particles 15. Such antenna bias voltage variation occurs for the following reasons.

The first reason is that the amount of electrical charge on the inner wall of the vacuum processing chamber 1 varies by the reaction product 14 adhered to the inner wall of the vacuum processing chamber 1. In other words, a capacitance between the plasma 13 and the inner wall of the vacuum processing chamber 1 varies by the adhesion of the reaction product 14 to the inner wall of the vacuum processing chamber 1. Because of the capacitance variation, the antenna bias voltage varies. As the film thickness of the reaction product 14 adhered to the inner wall of the vacuum processing chamber 1 becomes increases, the above capacitance decreases. That is, as the capacitance decreases, the direct current potential of the upper electrode 6 with respect to the vacuum processing chamber 1 increases. Since the antenna bias voltage is a negative value, the absolute value of the antenna bias voltage decreases as the adhesion of the reaction product 14 to the inner wall of the vacuum processing chamber 1 increases.

The second reason is that the particles 15 generated by the reaction product 14 being stripped from the inner wall of the vacuum processing chamber 1 float in plasma sheath generated between the plasma 13 and the inner wall of the vacuum processing chamber 1 (circumference of the plasma 13). Due to the incident electron to the particles floating in plasma, the particles 15 become negatively charged. As a result, the charged particles 15 are trapped in the plasma sheath. Although some electrons are taken up by the particles, the plasma maintains the electron density, resulting in increasing the total electron density which combining the electron charged in the particles and the electrons in the plasma Owing to the relationship between the antenna bias voltage Vdc and the electron density nₑ shown in the following formula (1), when the number of the particles 15 in the vacuum processing chamber 1 increases, the absolute value of the antenna bias voltage is reduced due to the increase in the electron density nₑ.

Vdc∝1/nₑⁿ (1)

Based on the above, the adhesion condition of the reaction product 14 to the inner wall of the vacuum processing chamber 1 or the particle count in the vacuum processing chamber 1 can be determined by monitoring the antenna bias voltage. In short, there is correspondence between the antenna bias voltage and the adhesion condition of the reaction product 14 to the inner wall of the vacuum processing chamber 1 or the particle count in the vacuum processing chamber 1. Naturally, a number of particles falling on the wafer 4 increases as a number of the particles 15 floating in the vacuum processing chamber 1 increases. Therefore, there is correspondence between the particle count on the wafer 4 and the antenna bias voltage.

In the present embodiment although the bias voltage of the upper electrode (the antenna bias voltage) is measured, it is possible that there is a similar correspondence between the bias voltage of the lower electrode or a wall surface of the vacuum processing chamber and the particle count.

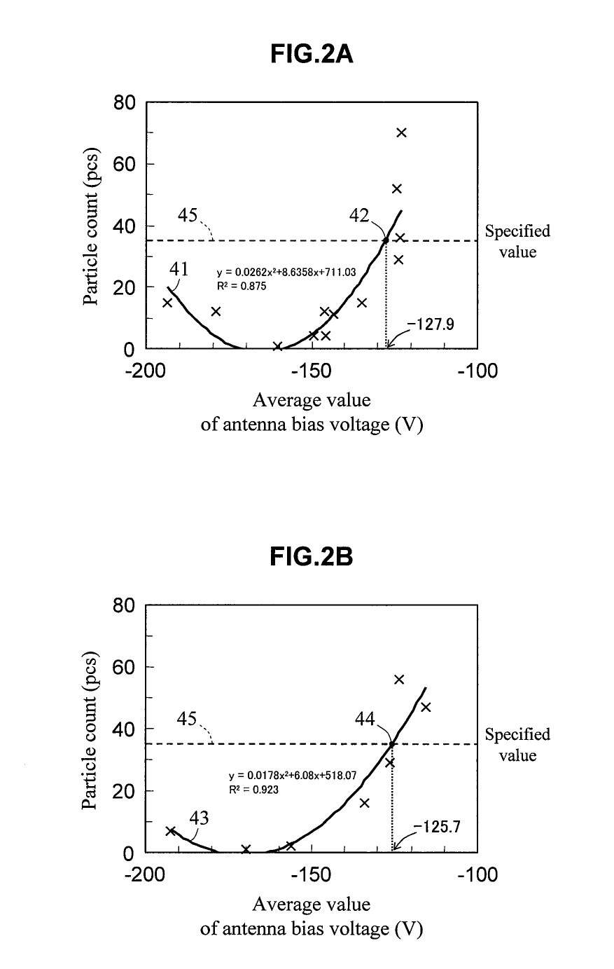

FIGS. 2A and 2B are diagrams showing the correspondence relationship between the average value of the antenna bias voltage and the number of particles (particle count) on the wafer 4. Here, the average value of the antenna bias voltage is an average value of the antenna bias voltage obtained during a single round of plasma processing. In the figure, the average value is used as a representative value for the antenna bias voltage during the single round of plasma processing. Furthermore, the particle count is the number of particles attached on the wafer 4 during each plasma processing. In this figure, the particles larger than 0.16 μm in diameter are counted.

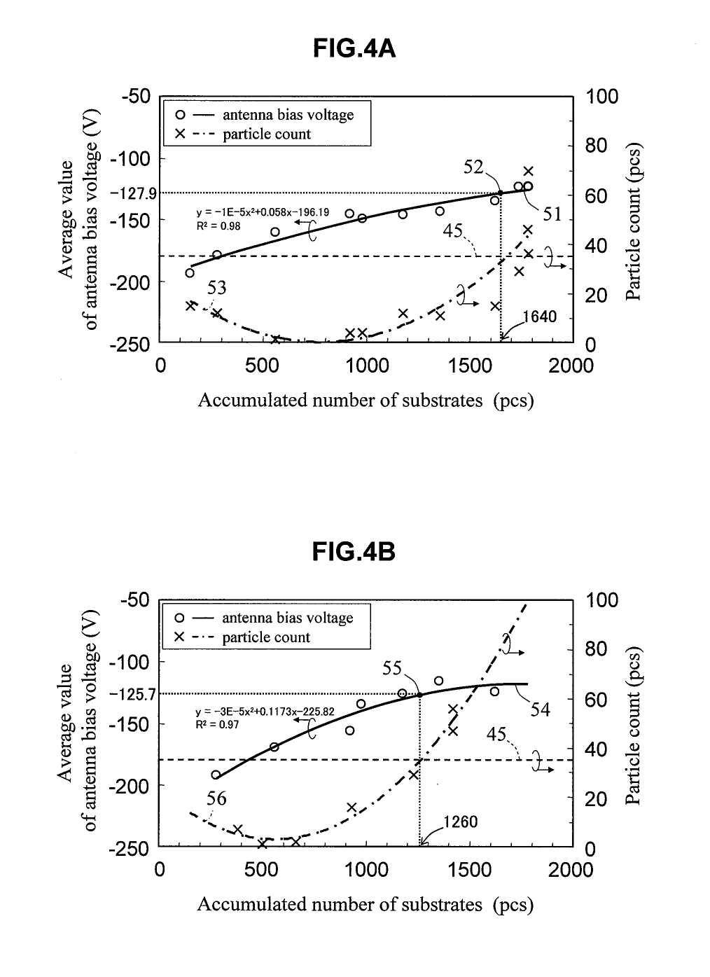

In FIGS. 2A and 2B, a horizontal-axis corresponds to the average value of the antenna bias voltage, whereas a vertical-axis corresponds to the particle count. FIGS. 2A and 2B show data obtained at different periods using the same plasma processing apparatus. At the beginning of each period, the inside of the vacuum processing chamber 1 is cleaned. Therefore, the inner wall of the vacuum processing chamber 1 is a reaction product 14-free condition. In addition, a curve line 41 shown in solid line in FIG. 2A and a curve line 43 shown in solid line in FIG. 2B are secondary regression curves obtained for the relationship between the average value of the antenna bias voltage and the particle count. Furthermore, although not shown in FIGS. 2A and 2B, the average value of the antenna bias voltage flatly increases during each period described later (See FIGS. 4A and 4B). Therefore, the horizontal-axis corresponds to the time course as well.

As shown in FIGS. 2A and 2B, the particle count temporarily decreases at first in both periods as the average value of the antenna bias voltage increases (its absolute value decreases). Then, the particle count flatly increases after the minimum value is reached.

The curve line 41 in FIG. 2A can be represented by the following formula (2) when the horizontal-axis is represented by x and the vertical-axis is represented by y. In addition, the curve line 43 in FIG. 2B can be represented by the following formula (3).

y=0.0262x²+8.6358x+711.03 (2)

y=0.0178x²+6.08x+518.07 (3)

For example, a specified value of the particle count on the wafer 4 is 35 counts as shown by dashed line 45 in FIGS. 2A and 2B. In this case, the average value of the antenna bias voltage that the curve line 41 reaches to 35 particle counts in FIG. 2A (x-coordinate of an intersection 42 of the curve line 41 with the dashed line 45) is —127.9V. In addition, the average value of the antenna bias voltage that the curve line 42 reaches to 35 particle counts in FIG. 2B (x-coordinate of an intersection 44 of the curve line 42 with the dashed line 45) is −125.7V.

In this way, there is correspondence between the average value of the antenna bias voltage and the particle count. Therefore, the time that the particle count reaches to the specified value can be predicted from the antenna bias voltage by obtaining the correspondence.

Now, in the plasma processing apparatus 10 of the present invention, the antenna bias voltage data obtained by the measurement circuit 9 is recorded in the data storage unit 21 after associating it with each plasma processing (for each plasma processing for a single wafer 4 here). The statistical value calculator 22 reads out the all antenna bias voltage data measured for the plasma processing currently performed from the data storage unit 21 at a fixed time period shorter than the plasma processing time to calculate its statistical value. In the present embodiment, the statistical value calculator 22 calculates the average value of the antenna bias voltage stored in the data storage unit 21 as the statistical value. Furthermore, the statistical value calculator 22 calculates a representative value of the antenna bias voltage measured during a single round of plasma processing. For example, instead of the average value, a median value may be calculated.

The statistical value calculator 22 stores the calculated statistical value in the statistical value memory unit 23 by associating it with data to identify the order in plasma processings including the plasma processing, such as ID specifying the plasma processing. In the present embodiment, the statistical value is calculated multiple times during a single round of the plasma processing and the statistical value for the same plasma processing is overwritten on the previous statistical value in the statistical value memory unit 23 and stored therein. Furthermore, it is necessary to use the all antenna bias voltage data for the calculation of the statistical value, for example, it is possible to use partial data such as the data excluding the data during a specified period at the beginning of the processing and the data during a specified period at the end of the processing. When the data excluding the data during a specified period at the end of the processing is used to calculate the statistical value, for example, it may adopt a configuration in which the statistical value calculator 22 checks whether the plasma processing corresponding to the statistical value is completed or not.

On the other hand, as is well known, for the wafer 4 for which the plasma processing has been completed, the number of particles attached on the wafer 4 is counted by using surface testing apparatus 31. The number of particles obtained in this way is associated with the corresponding statistical value and stored in the statistical value memory unit 23, by which the surface particle test can be omitted.

The correspondence acquisition unit 24 reads out the data of the average value of the antenna bias voltage and the particle count associated with thereof, obtained for the plasma processing after the last cleaning of the vacuum processing chamber 1 from the statistical value memory unit 23. The correspondence acquisition unit 24 calculates the regression formula (here, correspondence between the average value of the antenna bias voltage and the particle count) as shown in the formula (2) and the formula (3) based on the readout data. In the present embodiment, the correspondence acquisition unit 24 is configured so that the regression formula is calculated every time the particle count is stored in the statistical value memory unit 23. In addition, in the present embodiment, the regression formula is obtained from secondary polynomial approximation, but it may be obtained from any order of polynomial approximation, power approximation, or exponential approximation. Alternatively, a moving average may be used. When the correspondence acquisition unit 24 finishes calculating the regression formula and notifies the completion notification to the prediction unit 25.

The prediction unit 25 receiving the notification predicts the average value of the antenna bias voltage in which the particle count reaches to the specified value based on the regression formula obtained by the correspondence acquisition unit 24. In the present embodiment, the specified value of the particle count is pre-set in the prediction unit 25 and the prediction unit 25 calculates the average value of the antenna bias voltage that the regression formula obtained by the correspondence acquisition unit 24 equal to the specified value. In the examples of FIGS. 2A and 2B, since the correspondence is expressed in secondary regression formula, two average values of the antenna bias voltage equal to the specified value. However, as clearly shown in FIGS. 2A and 2B, a coefficient of the secondary of the regression formula is positive. In addition, the particle count does not exceed the specified value at immediately after the cleaning if cleaning is performed properly. Therefore, the prediction unit 25 selects a larger value of the two antenna bias voltages (the value with smaller absolute value) as a predicted value. The prediction unit 25 sends the calculated predicted value to the determination unit 26.

The determination unit 26 that received the predicted value compares the predicted value with the average value of the antenna bias voltage calculated by the statistical value calculator 22. When the average value of the antenna bias voltage calculated by the statistical value calculator 22 is larger than the predicted value, the determination unit 26 determines that the vacuum processing chamber 1 needs cleaning. Furthermore, when the average value of the antenna bias voltage calculated by the statistical value calculator 22 is smaller than the predicted value, the determination unit 26 determines that the vacuum processing chamber 1 does not need cleaning. In the present embodiment, the determination unit 26 is configured in a way that the determination is made every time the statistical value calculator 22 calculates the average value of the antenna bias voltage.

The determination unit 26 commands sending an alarm signal notifying the need of cleaning to notification unit, not shown in the figures, when the cleaning of the vacuum processing chamber 1 is necessary. At this time, the determination unit 26 may be configured in a way to stop the plasma processing in operation. Furthermore, the determination unit 26 may be configured in a way to send a request to the production management system 32 managing the production schedule of the manufacturing process including the present apparatus and other semiconductor manufacturing apparatus so that the lot which is planned to be processed by the plasma processing apparatus 10 is processed by other plasma processing apparatus.

The present embodiment determines whether the cleaning of the vacuum processing chamber 1 is necessary or not by comparing the average value of the antenna bias voltage calculated by the statistical value calculator 22 with the predicted value. However, the need for the cleaning may be determined by comparing the average value of the antenna bias voltage with the value subtracting a specified value (for example, 10V) from the above predicted value. In addition, the determination unit 26 may use the antenna bias voltage measured by the measurement circuit 9 instead of the statistical value of the antenna bias voltage calculated by the statistical value calculator 22 upon comparing the values.

As described above, according to the present embodiment, it can be determined whether the inside of the vacuum processing chamber is the condition that particles are likely to fall off or not even during the plasma processing. In addition, the plasma processing can be stopped before particles larger than a specified value falls on the wafer. Furthermore, cleaning can be performed at an appropriate time.

In the present embodiment, the configuration using the antenna bias voltage is described, however, an electrical potential of the chamber inner wall of the plasma processing apparatus 10 can be used instead. The present embodiment is described using the ECR etching apparatus, but dry etching apparatus using other plasma source such as CCP (Capacitively Coupled Plasma) or ICP (Inductively Coupled Plasma) may be used instead. In addition, the present embodiment is described using the plasma etching apparatus, but the configuration of filming apparatus using plasma CVD (Chemical Vapor Deposition) method may be taken.

Furthermore, in the present embodiment, the configuration comprising the determination unit 26 for determining the need for cleaning is described, however, similar effects can be achieved by a configuration in which an operator determines the need based on the predicted value. In addition, in the present embodiment, the data storage unit 21 and the statistical value memory unit 23 can be configured by heretofore known memory devices such as HDD (Hard Disk Drive). The statistical value calculator 22, the correspondence acquisition unit 24, prediction unit 25 and the determination unit 26 can be realized by an exclusive-use calculation circuit, or hardware having a processor and memories such as RAM or ROM, etc. and software stored in the memories and operating on the processor.

### SECOND EMBODIMENT

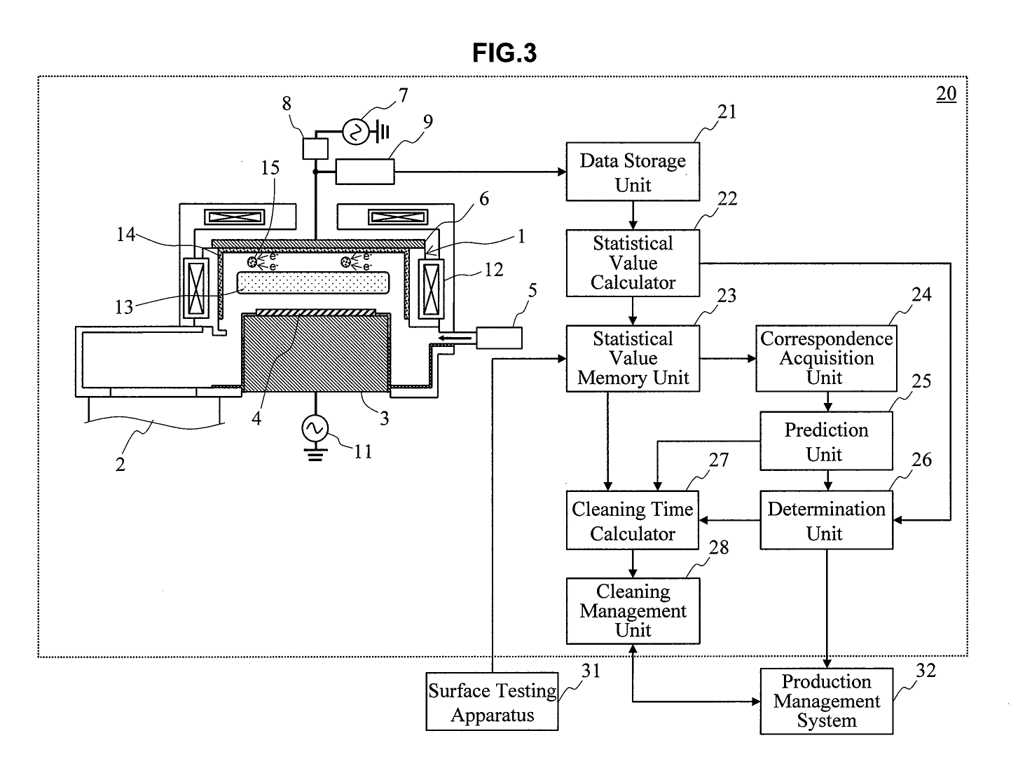

Next, a second embodiment according to the present invention is described in detail hereafter with reference to FIG. 3. FIG. 3 is a schematic diagram showing the plasma processing apparatus 20 of the present embodiment. As shown in FIG. 3, the plasma processing apparatus 20 further comprises a cleaning time calculator 27 and a cleaning management unit 28 in addition to the configuration of the above plasma processing apparatus 10. The cleaning time calculator 27 predicts the time that the average value of the antenna bias voltage exceeds the predicted value and calculates remaining process count or remaining process time of the wafer 4 until the next cleaning. The cleaning management unit 28 sets up an execution plan of the cleaning and based on the remaining process count or remaining process time calculated by the cleaning time calculator 27 and the production schedule obtained from the production management system 32 and sends the execution plan of the cleaning set up thereby to the production management system 32. Other configurations are same as those of the plasma processing apparatus 10 of the first embodiment, therefore, the same reference number is used for the parts having the same function and the explanation hereafter is omitted.

FIGS. 4A and 4B are diagrams showing the relationship between the average value of the antenna bias voltage and the accumulated number of substrates of the wafer 4 (circle in FIG. 4) and the relationship between the average value of the antenna bias voltage and the particle count on the wafer 4 (x mark in FIG. 4). In FIGS. 4A and 4B, a horizontal-axis corresponds to an accumulated number of substrates. Furthermore, in the present embodiment, since one wafer is processed in a single round of the plasma processing, the accumulated number of substrates becomes equal to the accumulated process count.

In addition, the left vertical-axis corresponds to the average value of the antenna bias voltage and the right vertical-axis corresponds to the particle count. FIGS. 4A and 4B show data obtained at different periods using the same plasma processing apparatus. At the beginning of each period, the inside of the vacuum processing chamber 1 is cleaned, and the inner wall of the vacuum processing chamber 1 is in a reaction product 14-free condition. In each plasma processing, the high-frequency power that the high-frequency power supply 7 applies to the upper electrode 6 is same and the high-frequency power that the high-frequency power supply 11 applied to the lower electrode 3 is the same. Furthermore, the period shown in FIG. 4A is the same as the period shown in FIG. 2A and the period shown in FIG. 4B is the same as the period shown in FIG. 2B.

In addition, a curve line 54 shown in solid line in FIG. 4A and a curve line 54 shown in solid line in FIG. 4B are secondary regression curves obtained for the relationship between the accumulated number of substrates and the average value of the antenna bias voltage. In addition, a curve line 53 shown in log dashed short dashed line in FIG. 4A and a curve line 56 shown in log dashed short dashed line in FIG. 4B are secondary regression curve obtained for the relationship between the accumulated number of substrates and the particle count. The particle count is the number of particles, larger than 0.16 μm in diameter, attached on the wafer 4.

As shown in FIGS. 4A and 4B, the average value of the antenna bias voltage monotonically increases as the accumulated number of substrates increases (its absolute value monotonically decreases) in both periods. In addition, the increasing rate of the average value of the antenna bias voltage decreases as the accumulated number of substrates increases, which is consistent with the above principle.

The curve line 51 in FIG. 4A can be represented by the following formula (4) when the horizontal-axis is represented by x and the vertical-axis is represented by y1. In addition, the curve line 54 in FIG. 4B can be represented by the following formula (5).

y1=−1×10⁻⁵x²+0.058x−196.19 (4)

y1=−3×10⁻⁵x²+0.1173x−225.82 (5)

As described in the first embodiment, according to the formula (2), in case that the specified value of the particle count on the wafer 4 is 35 counts, the average value of the antenna bias voltage that the particle count reach to 35 counts is −127.9V. In FIG. 4A, in the curve line 51, the accumulated number of substrates (x-coordinate of an intersection 52) is approximately 1640 when the average value of the antenna bias voltage becomes −127.9V.

In addition, according to the formula (3), the average value of the antenna bias voltage that the particle count reaches to 35 counts is −125.7V. In FIG. 4B, in the curve line 54, the accumulated number of substrates (x-coordinate of an intersection 55) is approximately 1260 when the average value of the antenna bias voltage becomes −125.7V.

In this way, there is correspondence between the average value of the antenna bias voltage and the accumulated number of substrates. Therefore, the accumulated number of substrates that reaches a specified average value of the antenna bias voltage can be predicted by obtaining the correspondence. As explained in the first embodiment, there is correspondence between the average value of the antenna bias voltage and the particle count. Therefore, the accumulated number of substrates in which the particle count reaches the specified value can be predicted by obtaining the correspondence between the average value of the antenna bias voltage and the particle count and the correspondence between the average value of the antenna bias voltage and the accumulated number of substrates.

In addition, as shown in the curve line 53 and the curve line 56 in FIGS. 4A and 4B, respectively, the particle count almost reach to the specified value in the accumulated number of substrates at the predicted average value of the antenna bias voltage based on the corresponding relationship shown in FIGS. 2A and 2B in both periods. The reason that the particle count does not completely matches with the specified value is that the curve line 53 and the curve line 56 in FIGS. 4A and 4B, respectively are regression curve lines obtained for the relationship between the accumulated number of substrates and the particle count and are expressed with different regression formulas from the regression curve obtained for the relationship between the average value of the antenna bias voltage and the particle count.

Now, in the plasma processing apparatus 20 of the present embodiment, in a similar manner to the first embodiment, the determination unit 26 determines whether it is necessary to clean the vacuum processing chamber 1 or not. When the determination unit 26 determines that it is not necessary to clean the vacuum processing chamber 1, the determination unit 26 notifies the decision to a cleaning time calculator 27.

The cleaning time calculator 27 that received the notification reads out the average value of the antenna bias voltage and the accumulated process count associated with thereof, obtained for the plasma processing after the last cleaning of the vacuum processing chamber 1 from the statistical value memory unit 23. In the present embodiment, the statistical value memory unit 23 stores the average values of the antenna bias voltage obtained for all plasma processing performed after the last cleaning. Therefore, the number of average values of the antenna bias voltage matches with the accumulated process count. Here, the cleaning time calculator 27 reads out the average values of the antenna bias voltage in an order that the plasma processing was performed to associate the average value of the antenna bias voltage read out with readout order (accumulated process count).

The cleaning time calculator 27 calculates the regression formula (correspondence between the average value of the antenna bias voltage and the accumulated process count) shown in the formula (4) and the formula (5) based on the obtained data. In the present embodiment, the regression formula is obtained from secondary polynomial approximation, but it may be obtained from any order of polynomial approximation, power approximation, or exponential approximation. Alternatively, a moving average may be used.

Once the regression formula is calculated, the cleaning time calculator 27 obtains the predicted value of the antenna bias voltage that reaches to the specified value of the particle count from the prediction unit 25. Then, based on the regression formula calculated, the cleaning time calculator 27 predicts a value of the accumulated process count reaches the predicted value of the antenna bias voltage. In examples of FIGS. 4A and 4B, since the correspondence is expressed in secondary regression formula, two values are obtained as the accumulated process count. However, as clearly shown in FIGS. 4A and 4B, a coefficient of the secondary of the regression formula is negative. In addition, after the cleaning, the antenna bias voltage monotonically increases as the accumulated process count increases. Therefore, the cleaning time calculator 27 selects a smaller value of the two accumulated process counts as a predicted value. In this way, when the predicted accumulated process count in which the particle count reaches the specified value is calculated, the cleaning time calculator 27 calculates remaining process count (here, the number of substrates) until the next cleaning. In the present embodiment, the cleaning time calculator 27 calculates the remaining process count by subtracting the current accumulated process count (here, the number of average values of the antenna bias voltage read out from the statistical value memory unit 23) from the predicted accumulated process count.

For example, in FIG. 4A, when the accumulated number of substrates is 1000 pieces and the accumulated number of substrates predicted by the cleaning time calculator 27 is 1600 pieces. In this case, the number of substrates which can be processed until the next cleaning becomes 600 pieces (the remaining process count is 600 counts). The cleaning time calculator 27 sends the predicted remaining process count to the cleaning management unit 28.

As described above, in the present embodiment, the cleaning time calculator 27 allows the remaining process count to the next cleaning can be predicted. Furthermore, the regression formula calculated by the cleaning time calculator 27 varies depending on the accumulated process count at the time of regression formula calculation. However, as the next cleaning time gets closer, number of data used for calculating the regression formula increases, the prediction accuracy is improved. The present embodiment is described with regard to the configuration in which the number of average values of the antenna bias voltage read out from the statistical value memory unit 23 is used as the accumulated process count. However, it may take a configuration in which the statistical value memory unit 23 stores the average value of the antenna bias voltage correlated with the accumulated process count at the time of obtaining the average value of the antenna bias voltage. In addition, it may take a configuration in which the statistical value memory unit 23 stores the average value of antenna bias voltage correlated with the accumulated process time at the time of obtaining the average value of the antenna bias voltage. In this case, the cleaning time calculator 27 calculates the correspondence (the regression formula) between the average value of the antenna bias voltage and the accumulated process time and predicts the accumulated process time that reaches to the predicted average value of the antenna bias voltage based on the regression formula calculated. Then, the cleaning time calculator 27 calculates the remaining process time until the next cleaning.

When the cleaning management unit 28 receives the process count which can be performed until the next cleaning (remaining process count) or the process time which can be performed until the next cleaning (remaining process time) from the cleaning time calculator 27, it obtains the production schedule of the plasma processing apparatus 20 from the above-mentioned production management system 32. Here, the production schedule is the data containing the number of substrates to be processed and process order (priority). When the production schedule is obtained, the cleaning management unit 28 determines the cleaning time of the vacuum processing chamber 1 based on the data received from the cleaning time calculator 27 and the production schedule. For example, the cleaning management unit 28 determines the cleaning time as the time of the completion of the plasma processing to a specified lot. Then, the decided cleaning time is sent to the production management system 32. When the production management system 32 receives the cleaning time from the cleaning management unit 28, it sets up a new production schedule to have another plasma processing apparatus process the lot which is originally planned to be processed by the plasma processing apparatus 20 at the cleaning time.

Furthermore, with the above configuration, the cleaning time calculator 27 and cleaning management unit 28 can be realized by, for example, an exclusive-use calculation circuit, or hardware having a processor and memories such as RAM or ROM, etc. and software stored in the memories and operating on the processor. In addition, it is not necessary to configure the above-mentioned data storage unit 21, the statistical value calculator 22, the statistical value memory unit 23, the correspondence acquisition unit 24, the prediction unit 25, the determination unit 26, the cleaning time calculator 27 and the cleaning management unit 28 separately, for example, it can be realized by a computer comprising central processor, storage device, input device such as keyboard and a display device.

According to the above configuration, the operation rate of the apparatus can be improved and, in addition to the effects to be obtained by the first embodiment, it can provide the effect that the production efficiency of the manufacturing process including the plasma processing apparatus 20 is improved.

On the other hand, it often occurs that lots entering the production process later need to be processed with priority over the preceding lots. In such a case, the production management system 32 modifies the production schedule of each apparatus belonging to the production process. At this time, it is possible that the lot to be processed by the plasma processing apparatus 20 is to be modified. To deal with such situation, it is preferable to have a configuration in which the cleaning management unit 28 obtains the modified production schedule when the production management system 32 modified the production schedule and re-determines the cleaning time based on the obtained production schedule.

As described above, a determination can be made as to whether the inside of the vacuum processing chamber is a state in which particles are likely to fall off or not even during the plasma processing. Therefore, the plasma processing can be stopped before particles larger than a specified size falls on the wafer. In addition, the cleaning time can be determined when the particle count increases. As a result, the amount of reaction product adhered to the inner wall of the vacuum processing chamber can be always maintained within a specified range to prevent substandard particles from attaching on the workpiece. Furthermore, the operation rate of the apparatus can be improved since the production schedule can be determined based on the determined cleaning time.

In addition, the present invention is not limited to the embodiment described above, and various modifications and applications are possible within the scope to which this invention is effective. For example, in each embodiment as described above, the examples applied to an ECR type plasma etching apparatus are described, however, the present invention is not limited to the etching apparatus and it can be applied to a film formation apparatus. In other words, the present invention is applicable to any plasma processing apparatus for performing plasma processing to a workpiece with plasma generated in the vacuum processing chamber.

Moreover, in each embodiment as described above, the inside condition of the vacuum processing chamber is determined by the antenna bias voltage, but any physical values can be used for determining the inside condition of the vacuum processing chamber as long as the physical value fluctuates according to the amount of electrical charge occurred between the inner wall of the vacuum processing chamber and the plasma generated in the vacuum processing chamber. For example, it is possible to determined the inside condition of the vacuum processing chamber by a substrate bias potential. However, since an absolute value of the substrate bias potential is smaller than that of the antenna bias voltage, the detection accuracy may decrease. Therefore, it is preferable to determine the condition by the antenna bias voltage.

Furthermore, a program for having a computer execute a part of or all of the statistical value calculator 22, the correspondence acquisition unit 24, the prediction unit 25, the determination unit 26, the cleaning time calculator 27 and the cleaning management unit 28, may be provided to related parties or third parties via electrical communication lines such as the internet or by storing the program on a computer readable recording medium. For example, when the program instructions are expressed with electrical signals, optical signals, magnetic signals or the like and those signals are sent on a carrier wave, it is possible to provide those programs via transmission media such as coaxial cable, copper wiring, optical fibers or the like. In addition, as the computer readable recording medium, it is possible to use optical media such as CD-ROM, DVD-ROM, and the like, magnetic media such as flexible disk, or semiconductor memory such as flash memory or RAM.

The present invention has effects to prevent a workpiece to attach particles larger than a specified size and is useful as a plasma processing apparatus, a plasma processing method, and a cleaning time prediction program.

What is claimed is:

1. A plasma processing apparatus for plasma processing of a workpiece in a vacuum processing chamber using plasma generated in the vacuum processing chamber by applying high-frequency power to a plasma excitation electrode, comprising:
a unit obtaining a physical value which varies according to an amount of electrical charge between an inner wall of the vacuum processing chamber and the plasma generated in the vacuum processing chamber;
a unit recording by associating the obtained physical value with a number of particles attached on the workpiece during the plasma processing in which the physical value is obtained;
a unit obtaining a correspondence between the physical value and the number of particles based on the physical values and the numbers of particles obtained from a multiple rounds of the plasma processing; and
a unit predicting the physical value at which the number of particles reaches to a pre-determined specified value based on the correspondence.

2. A plasma processing apparatus according to claim 1, further comprising:
a unit determining whether a cleaning of the vacuum processing chamber is needed or not by comparing the predicted physical value with the physical value obtained during the plasma processing thereafter.

3. A plasma processing apparatus according to claim 1, further comprising:
a unit obtaining a correspondence between the physical values obtained from a multiple rounds of the plasma processing and an accumulation process time or an accumulation process count of the vacuum processing chamber after the cleaning of the vacuum processing chamber; and
a unit predicting a remaining process time reaching to the predicted physical value based on the correspondence between the physical value and the accumulated process time, or a remaining process count reaching to the predicted physical value based on the correspondence between the physical value and the accumulated process count.

4. A plasma processing apparatus according to claim 3, further comprising:
a unit determining a cleaning time of the vacuum processing chamber based on the predicted remaining process time or the predicted remaining process count and a production schedule for workpieces to be plasma-processed.

5. A plasma processing apparatus according to claim 4, wherein, in a case that the production schedule is modified, the unit determining the cleaning time determines the cleaning time of the vacuum processing chamber based on the modified production schedule.

6. A plasma processing apparatus according to claim 1, wherein the physical value is a self-bias potential of the plasma excitation electrode.

7. A plasma processing method for plasma processing of a workpiece in a vacuum processing chamber using plasma generated in the vacuum processing chamber by applying high-frequency power to a plasma excitation electrode, comprising the steps of:
obtaining a physical value which varies according to an amount of electrical charge between an inner wall of the vacuum processing chamber and the plasma generated in the vacuum processing chamber;
associating the obtained physical value with a number of particles attached on the workpiece during the plasma processing in which the physical value is obtained;
obtaining a correspondence between the physical value and the number of particles based on the physical values and the numbers of particles obtained from a multiple rounds of the plasma processing; and
predicting the physical value at which the number of particles reaches to a pre-determined specified value based on the correspondence.

8. A plasma processing method according to claim 7, further comprising a step of:
determining whether a cleaning of the vacuum processing chamber is needed or not by comparing the predicted physical value with the physical value obtained during the plasma processing thereafter.

9. A plasma processing method according to claim 7, further comprising the steps of:
obtaining a correspondence between the physical values obtained from a multiple rounds of the plasma processing and an accumulation process time or an accumulation process count of the vacuum processing chamber after the cleaning of the vacuum processing chamber; and
predicting a remaining process time reaching to the predicted physical value based on the correspondence between the physical value and the accumulated process time, or a remaining process count reaching to the predicted physical value based on the correspondence between the physical value and the accumulated process count.

10. A plasma processing method according to claim 9, further comprising a step of:
determining a cleaning time of the vacuum processing chamber based on the predicted remaining process time or the predicted remaining process count and a production schedule for workpieces to be plasma-processed.

11. A plasma processing method according to claim 10, wherein, in a case that the production schedule is modified, the cleaning time of the vacuum processing chamber is determined based on the modified production schedule.

12. A plasma processing method according to claim 7, wherein the physical value is a self-bias potential of the plasma excitation electrode.

13. A cleaning time prediction program for predicting a cleaning time of a plasma processing apparatus for plasma processing of a workpiece in a vacuum processing chamber using plasma generated in the vacuum processing chamber by applying high-frequency power to a plasma excitation electrode, comprising the steps of:
recording by associating a physical value, which varies according to an amount of electrical charge between an inner wall of the vacuum processing chamber and the plasma generated in the vacuum processing chamber, with a number of particles attached on the workpiece during the plasma processing in which the physical value is obtained;
obtaining a correspondence between the physical value and the number of particles based on the physical values and the numbers of particles obtained from a multiple rounds of the plasma processing;
predicting the physical value at which the number of particles reaches to a pre-determined specified value based on the correspondence;
obtaining a correspondence between the physical value obtained from a multiple rounds of the plasma processing and an accumulated process time or an accumulated process count of the vacuum processing chamber after the cleaning of the vacuum processing chamber; and
predicting a remaining process time reaching to the predicted physical value based on the correspondence between the physical value and the accumulated process time, or a remaining process count reaching to the predicted physical value based on the correspondence between the physical value and the accumulated process count.
